(19) United States
(12) Patent Application Publication
(10) Pub. No.: US 2024/0371612 A1
(43) Pub. Date: Nov. 7, 2024

(54) SUBSTRATE PROCESSING APPARATUS

(71) Applicant: JUSUNG ENGINEERING CO., LTD., Gwangju-si (KR)

(72) Inventors: Young Rok KIM, Seongnam-si (KR); Ji Hun LEE, Yongin-si (KR)

(21) Appl. No.: 18/773,716

(22) Filed: Jul. 16, 2024

Related U.S. Application Data
(63) Continuation of application No. PCT/KR2023/001896, filed on Feb. 9, 2023.

(30) Foreign Application Priority Data
Feb. 14, 2022 (KR) 10-2022-0019188

(51) Int. Cl. H01J 37/32; C23C 16/48

(52) U.S. Cl. CPC H01J 37/32651; C23C 16/482; H01J 37/3211; H01J 37/32119; H01J 2237/3321

(57) ABSTRACT

A substrate processing apparatus includes: a chamber having a sidewall; a susceptor configured to mount a substrate inside the chamber; an upper dome surrounding an upper surface of the chamber and formed of a transparent dielectric material; an antenna disposed above the upper dome to generate inductively-coupled plasma; and an electromagnetic wave shield housing disposed to surround the antenna, wherein the electromagnetic wave shield housing may be heated by a heater.

### CROSS-REFERENCE TO RELATED APPLICATIONS

This application is a continuation of and claims priority to PCT/KR2023/001896 filed on Feb. 9, 2023, which claims priority to Korea Patent Application No. KR 10-2022-0019188 filed on Feb. 14, 2022, the entireties of which are both hereby incorporated by reference.

### TECHNICAL FIELD

The present disclosure relates to a substrate processing apparatus, and more particularly, to an epitaxial plasma enhanced chemical vapor deposition apparatus for depositing a thin film by rapidly heating a substrate at high temperature using a lamp heater.

### BACKGROUND

In manufacturing of a semiconductor, a single-crystalline silicon thin film having the same crystal structure as a single-crystalline silicon substrate is deposited on the substrate. An inorganic insulating material such as a silicon oxide is deposited and patterned and then the single-crystalline thin film is formed a single-crystalline region only in a silicon-exposed portion of a substrate surface, which refers to as selective epitaxial growth (SEG).

In addition, in manufacturing of a thin-film solar cell on a large-area substrate, a P layer receiving sunlight, an I layer forming electron-hole pairs, and an N layer serving as a counter electrode to the P layer are basically provided. Similarly, a liquid crystal display device is basically provided with an array element and a color filter element, respectively formed on an array and a color filter substrate.

To manufacture a thin film device for a solar cell and a liquid crystal display, a photolithography process is required to be performed several times. Such a photolithography process includes a thin film deposition process, a photoresist coating process, an exposure and development process, and an etching process, and involves various process such as a cleaning process, a bonding process, and a cutting process.

Plasma enhanced chemical vapor deposition (hereinafter referred to as “PECVD”) is a method of forming a thin film in a state in which a radio-frequency (RF) high voltage is applied to an antenna or an electrode to excite a reaction gas into a plasma state inside a chamber.

Recently, internal walls of a chamber have been designed with quartz and an upper dome and a lower dome have been designed in an upper portion and a lower portion of the chamber with quartz to prevent foreign objects or byproducts, generated during a deposition process using PECVD, from adhering to the internal walls of the chamber.

In such a deposition process using plasma enhanced chemical vapor deposition, a pressure inside a chamber may be maintained at several mTorr, and a base vacuum state may be maintained in an ultra-high vacuum state of 10E-9 Torr to significantly decrease the number of foreign objects or byproducts generated during the deposition process and the deposition process reduces time required for the deposition process, resulting in improved production yield.

Such plasma enhanced chemical vapor deposition encounters an issue, in which an antenna disposed on an upper dome is heated by infrared rays to reduce plasma stability, and an issue in which the antenna reduces uniformity of a thin film through infrared reflection. Accordingly, there is a need for a novel plasma source and thin film deposition method.

### SUMMARY

An aspect of the present disclosure is to provide a substrate processing apparatus which includes a heater therein to significantly reduce heat loss of an electromagnetic wave shield housing surrounding an antenna and is coupled to a chamber or a connection portion of the chamber through a heat insulating spacer to perform heat insulation, thereby providing a stable operation.

Another aspect of the present disclosure is to provide a substrate processing apparatus suppressing damage to a product, caused by a high temperature, through a cooling housing surrounding an electromagnetic wave shield housing.

Another aspect of the present disclosure is to provide an antenna which may stably generate plasma even by external infrared heating and a substrate processing apparatus including the antenna.

Another aspect of the present disclosure is to provide a substrate processing apparatus reducing contamination of an upper dome and a lower dome.

Another aspect of the present disclosure is to provide a substrate processing apparatus securing uniformity resulting from uniform substrate heating achieved due to a shape of a clamp, a shape of an antenna housing, and gold plating.

Another aspect of the present disclosure is to provide a substrate processing apparatus simultaneously providing uniform infrared heating and uniform plasma.

Another aspect of the present disclosure is to provide a substrate processing apparatus providing a uniform process using an antenna, generating plasma, and a resistive heater embedded in an antenna housing disposed to surround the antenna.

A substrate processing apparatus according to an embodiment includes: a chamber having a sidewall; a susceptor configured to mount a substrate inside the chamber; an upper dome surrounding an upper surface of the chamber and formed of a transparent dielectric material; an antenna disposed above the upper dome to generate inductively-coupled plasma; and an electromagnetic wave shield housing disposed to surround the antenna. The electromagnetic wave shield housing may be heated by a heater.

In an embodiment, the substrate processing apparatus may further include: a thermally insulating spacer thermally insulated from the electromagnetic wave shield housing and an upper surface of the chamber.

In an embodiment, the thermally insulating spacer may have a shape of a ring formed of a ceramic material.

In an embodiment, the substrate processing apparatus may further include: a cooling housing disposed to be spaced apart from the electromagnetic wave shield housing to surround the electromagnetic wave shield housing. The cooling housing may be cooled by a refrigerant.

In an embodiment, a temperature of the electromagnetic wave shield housing may range from 200 degrees Celsius to 600 degrees Celsius.

In an embodiment, the substrate processing apparatus may further include: a funnel-shaped lower dome covering a lower surface of the chamber and formed of a transparent dielectric material; a concentric lamp heater disposed on a lower surface of the lower dome; a ring-shaped upper liner disposed on an internal side of the chamber, surrounding a lower side edge of the upper dome, and formed of a dielectric material; a ring-shaped lower line disposed on an internal side of the chamber, surrounding an internal circumferential surface of an upper edge of the lower dome, and formed of a dielectric material; and a reflector disposed on a lower surface of the concentric lamp heater.

In an embodiment, the antenna may include two one-turn unit antennas, the two one-turn unit antennas may be disposed to overlap each other on an upper surface and a lower surface, the two one-turn unit antennas may be connected to a radio-frequency (RF) power supply in parallel, and a width direction of the one-turn unit antenna may stand upright.

In an embodiment, the one-turn unit antenna may have a shape of a strip line having a width greater than a thickness of the strip line, a width direction of the one-turn unit antenna may stand upright, and a ratio (W/t) of the width (W) to the thickness (t) may be 10 or more.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a conceptual diagram illustrating a home position in a plasma enhanced chemical vapor deposition apparatus according to an embodiment of the present disclosure.

FIG. 2 is a conceptual diagram illustrating an up-position in the plasma enhanced chemical vapor deposition apparatus of FIG. 1.

FIG. 3 is a conceptual diagram, taken in another direction, illustrating the plasma enhanced chemical vapor deposition apparatus of FIG. 1.

FIG. 4 is a cutaway perspective view illustrating an upper liner, a lower liner, and a lower dome of the plasma enhanced chemical vapor deposition apparatus of FIG. 1.

FIG. 5 is a perspective view illustrating an antenna of the plasma enhanced chemical vapor deposition apparatus of FIG. 1.

FIG. 6 is a plan view illustrating the antenna of FIG. 5.

FIG. 7 is a plan view illustrating an antenna according to another embodiment of the present disclosure.

FIG. 8 is a conceptual diagram illustrating a plasma enhanced chemical vapor deposition apparatus according to another embodiment of the present disclosure.

FIG. 9 is a conceptual diagram illustrating a plasma enhanced chemical vapor deposition apparatus according to another embodiment of the present disclosure.

FIG. 10 is a conceptual diagram illustrating a plasma enhanced chemical vapor deposition apparatus according to another embodiment of the present disclosure.

### DETAILED DESCRIPTION

The present disclosure provides a plasma enhanced chemical vapor deposition apparatus including an antenna for inductively-coupled plasma which has high transmittance to infrared rays emitted from a lamp heater, is not heated, and generates uniform inductively-coupled plasma.

A high process temperature of about 900 degrees Celsius is typically required to grow single-crystalline silicon-germanium or single-crystalline silicon on a substrate. In semiconductor manufacturing using such selective epitaxial growth, it is easy to fabricate a semiconductor device having a three-dimensional structure, such as a finFET, which is difficult to be fabricated using a flat panel technology according to the related art.

When a lamp heater is applied for a process temperature of 900 degrees Celsius, an antenna generating inductively-coupled plasma in a process container is heated by the lamp heater to increase a temperature, so that a resistance value is increased. Accordingly, the antenna cannot generate efficient inductively-coupled plasma due to energy consumption through ohmic heating. Also, the antenna may generate a shadow for infrared rays, reflected from an electromagnetic wave shield housing, to provide temperature non-uniformity to a substrate. To achieve process stability, the electromagnetic wave shield housing may be heated to shield electromagnetic waves while maintaining the antenna at a constant temperature.

In addition, there is a need for an antenna for inductively-coupled plasma which is not heated by a lamp heater and does not generate a shadow.

In addition, an electromagnetic wave shield housing disposed to surround the antenna may reflect a portion of infrared rays emitted from the lamp heater, and remaining infrared rays may be absorbed and heated by the electromagnetic wave shield housing to reduce reliability. A spatially non-uniform temperature distribution in the electromagnetic wave shield housing may provide spatially non-uniform blackbody radiation. Accordingly, the electromagnetic wave shield housing may be heated to a uniform temperature using an additional resistive heater, and may provide spatially uniform blackbody radiation. The electromagnetic wave shield housing may be heated to a temperature of 200 degrees Celsius to 600 degrees Celsius to increase heat loss when it is in direct thermal contact with a chamber. Accordingly, the electromagnetic wave shield housing may be insulated from the chamber to significantly reduce the heat loss. For example, a thermally insulating spacer may be disposed between the electromagnetic wave shield housing and the chamber to reduce the heat loss of the electromagnetic wave shield housing. The electromagnetic wave shield housing may be electrically grounded through an additional conductive line. The thermally insulating spacer may have a ring shape and may be formed of a ceramic material. The thermally insulating spacer may be formed of a porous ceramic material.

In a chemical vapor deposition apparatus according to the related art having an upper dome and a lower dome, a process gas is injected into the upper dome and is exhausted from the upper dome. Accordingly, the gas may flow within the upper dome with a predetermined directivity to reduce uniformity of a thin film. The process gas, supplied from the upper dome, may be introduced into the lower dome to deposit an abnormal thin film on the lower dome.

According to the present disclosure, a purge gas may be supplied to a lower dome and a process gas may be supplied to an upper dome to prevent the process gas from flowing into the lower dome, and thus deposition of an abnormal thin film on the lower dome may be suppressed. In addition, uniform plasma may be generated to form a uniform thin film without rotating a substrate.

A chemical vapor deposition apparatus according to the related art, including an upper dome and a lower dome, uses a liner to prevent an unnecessary thin film from being deposited on an internal wall of a chamber. The liner may be periodically replaced or cleaned.

In the present disclosure, a lower side of an upper liner and a lower liner may have inclined surfaces such that a purge gas supplied from a lower dome is injected toward an upper dome and more lamp heaters are installed. A gap between a susceptor and a liner may be maintained to be narrow, and thus the purge gas supplied from the lower dome may be injected toward the upper dome to cause a pressure difference. Due to the narrow gap between the susceptor and the liner, the process gas injected into the upper dome may stay only inside the upper dome to prevent contamination of the lower liner. The lower liner may be formed of an opaque quartz material, and may scatter infrared rays of a lamp heater to provide uniform heating of the substrate.

In the present disclosure, an antenna for inductively-coupled plasma may be disposed to be spaced apart from an upper dome, a wire constituting the antenna may have a strip line shape, and a width direction of a strip line may be vertically aligned. Accordingly, infrared rays incident from a direction of a lower dome may be minimally incident to the antenna. As a result, the antenna may suppress heating performed by infrared rays, and infrared rays reflected from an electromagnetic wave shield housing may heat a substrate while significantly reducing a shadow.

In the present disclosure, an electromagnetic wave shield housing surrounding an antenna and shielding electromagnetic waves may be plated with gold such that infrared rays are reflected to be re-incident on a substrate again. In addition, the electromagnetic wave shield housing may have a cylindrical shape rather than a dome shape, and may reduce re-incidence heating of the antenna caused by infrared reflection.

In the present disclosure, a lamp heater disposed below a lower dome may be a ring-shaped lamp heater, and may be provided in plural. The ring-shaped lamp heaters are grouped together to independently control power to uniformly heat a substrate.

In the present disclosure, a turbo molecular pump (TMP) connected to an exhaust portion of a chamber may allow base vacuum to be maintained inside the chamber, and may generate stable plasma at a pressure of several Torr or less even during a process.

Plasma enhanced chemical vapor deposition of the present disclosure may reduce performance degradation caused by infrared heating of an antenna for inductively-coupled plasma disposed on an upper dome and may re-provide infrared rays, reflected from an electromagnetic wave shield housing, to a substrate to form a uniform thin film on the substrate at a high speed.

Hereinafter, embodiments of the present disclosure will be described below more fully with reference to accompanying drawings. The present disclosure may, however, be embodied in different forms and should not be constructed as limited to the embodiments set forth herein. Rather, these embodiments are provided so that this disclosure will be thorough and complete, and will fully convey the scope of the present disclosure to those skilled in the art.

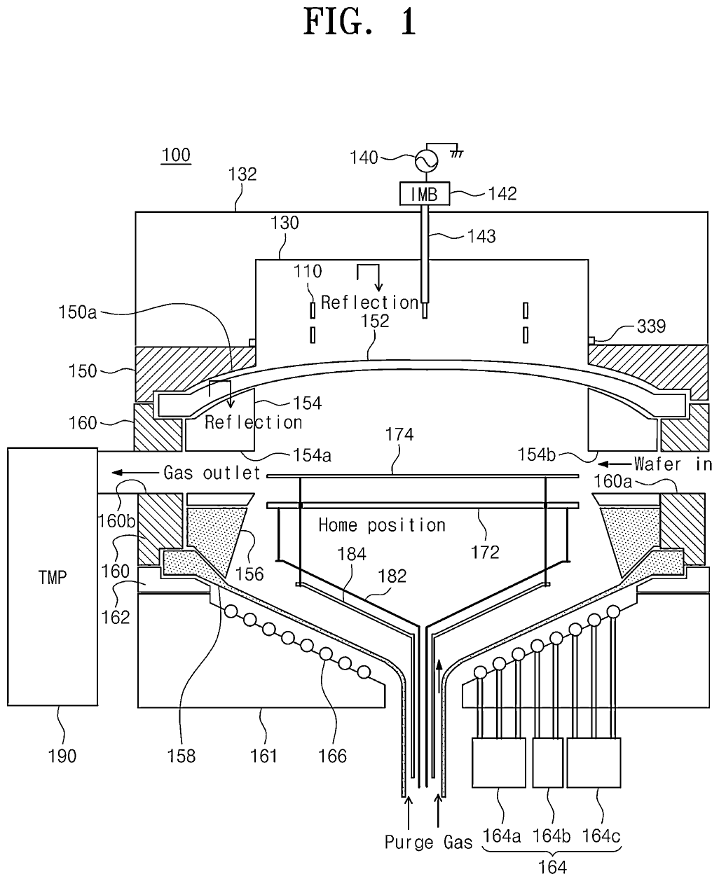

FIG. 1 is a conceptual diagram illustrating a home position in a plasma enhanced chemical vapor deposition apparatus according to an embodiment of the present disclosure.

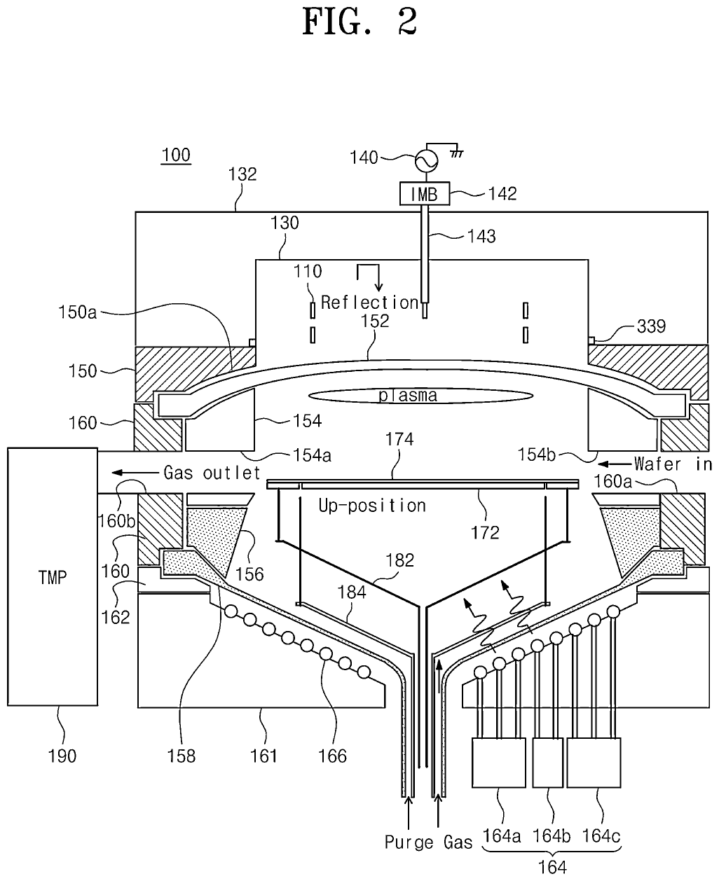

FIG. 2 is a conceptual diagram illustrating an up-position in the plasma enhanced chemical vapor deposition apparatus of FIG. 1.

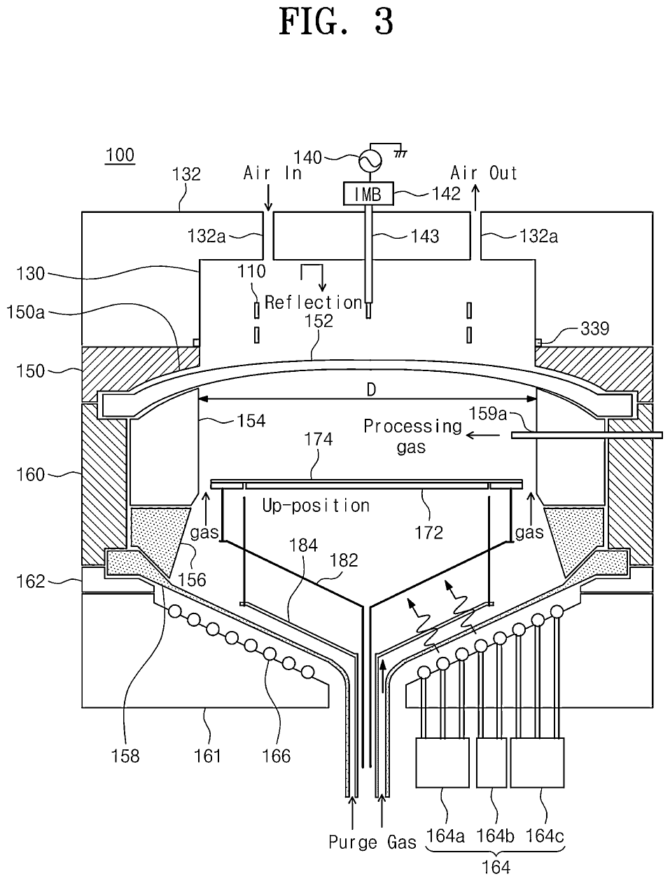

FIG. 3 is a conceptual diagram, taken in another direction, illustrating the plasma enhanced chemical vapor deposition apparatus of FIG. 1.

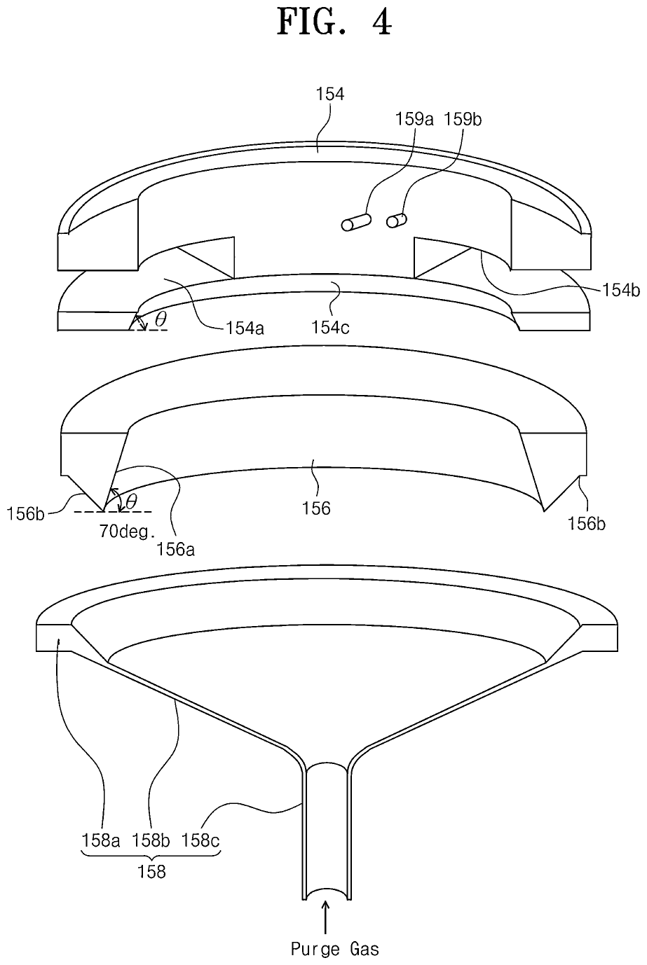

FIG. 4 is a cutaway perspective view illustrating an upper liner, a lower liner, and a lower dome of the plasma enhanced chemical vapor deposition apparatus of FIG. 1.

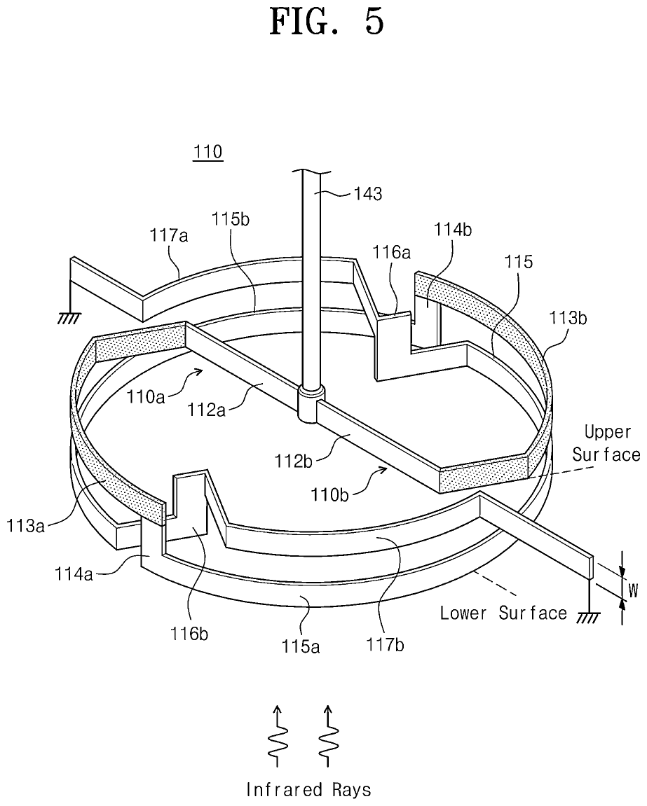

FIG. 5 is a perspective view illustrating an antenna of the plasma enhanced chemical vapor deposition apparatus of FIG. 1.

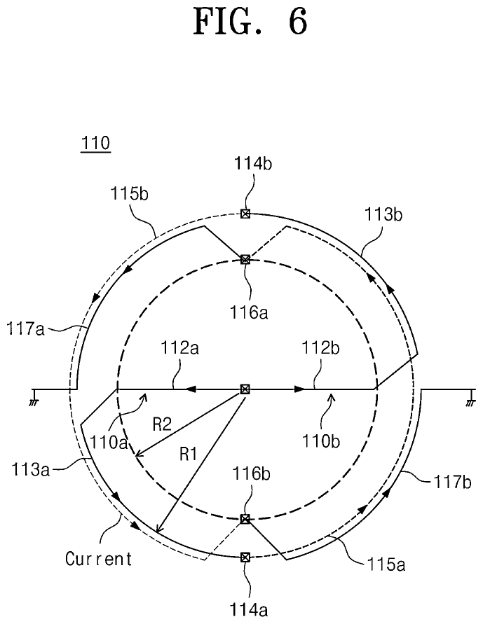

FIG. 6 is a plan view illustrating the antenna of FIG. 5.

Referring to FIGS. 1 to 6, a plasma enhanced chemical vapor deposition apparatus 100 according to an embodiment may include a chamber 160 having a sidewall; a susceptor 172 mounting a substrate inside the chamber 160; an upper dome 152 surrounding an upper surface of the chamber 160 and formed of a transparent dielectric material; an antenna 110 disposed above the upper dome 152 to generate inductively-coupled plasma; and an electromagnetic wave shield housing 130 disposed to surround the antenna 110. The electromagnetic wave shield housing 130 may be heated by a heater.

The antenna 110 may include two one-turn unit antennas. The two one-turn unit antennas may be disposed to overlap each other on upper and lower surfaces, and may be connected to a radio-frequency (RF) power supply 140 in parallel. A width direction of the one-turn unit antenna may stand upright.

The chamber 160 may be formed of a conductive material, and an internal space of the chamber 160 may have a cylindrical shape and an external shape of the chamber 160 may be a cuboidal shape. The chamber 160 may be cooled by cooling water. The chamber 160, the upper dome 152, and the lower dome 158 may be coupled to provide an airtight space. The chamber 160 may include a substrate entrance 160a formed on a side surface of the chamber 160 and an exhaust port 160b formed on a side surface opposing the substrate entrance 160a. The exhaust port 160b may be connected to a high-vacuum pump 190. The high-vacuum pump 190 may be a turbo molecular pump. The high-vacuum pump 190 may maintain a low base pressure, and may maintain a pressure of several Torr or less even during a process. An upper surface of the exhaust port 160b may be even with or lower than an upper surface of the substrate entrance 160a.

For example, when the upper surface of the exhaust port 160b is even with the upper surface of the substrate entrance 160a, the upper surface of the susceptor 172 may be changed to a position, higher than a position of lower surfaces of the exhaust port 160b and the substrate entrance 160a during a process. Accordingly, symmetry of the inside of the chamber 160 may be increased and a flow of process gas may be improved, and thus uniform thin film deposition may be provided.

The susceptor 172 may mount the substrate 174 when the substrate 174 is introduced through the substrate entrance 160a formed on the side surface of the chamber 160. The susceptor 172 may have the same plate shape as the substrate 174 and may be formed of a metal or a graphite material having improved thermal conductivity. The susceptor 172 may be heated by infrared rays and may heat the substrate 174 by heat transfer. During the process, an upper surface of the susceptor 172 may be higher than lower surfaces of the exhaust port 160b and the substrate entrance 160a. The susceptor 172 may rotate.

A first lifter 184 may extend along a central axis of the lower dome 158 and may include a first lifter body having a tripod shape and a first lift pin. The first lifter 184 and the second lifter 182 may have a coaxial structure. When the substrate 174 is transferred into the chamber, the first lifter 184 may be lifted at a storage position or a home position to support the substrate 174. Then, the first lifter 184 may descend to load the substrate 174 on the susceptor 172. A material of the first lifter 184 may be quartz or a metal. The first lifter 184 may be vertically moved by a drive shaft.

The second lifter 182 may extend along the central axis of the lower dome 158 and may include a second lifter body having a tripod shape and a second lift pin. The second lifter 182 may lift the susceptor 172, on which the substrate 174 is mounted, to a process position or a lifting position. The process position may be disposed on a substantially same plane as a lower surface of a second opening 154b for introducing the substrate in the upper liner 154. In addition, the process position may be disposed on substantially the same plane as a lower surface of the first opening 154a of the upper liner 154 for exhausting a gas. Accordingly, a distance between the susceptor 172 and the upper liner 154 may be significantly reduced at the process position. A material of the second lifter 182 may be quartz or a metal. The second lifter 182 may be vertically moved by a drive shaft.

The upper dome 152 may be quartz or sapphire as a transparent dielectric material. The upper dome 152 may be inserted into and coupled to a step formed on the upper surface of the chamber 160. A coupling portion of the upper dome 152 coupled to the chamber 160 may have a washer shape to achieve vacuum sealing. The upper dome 152 may have an arc shape or an elliptical shape. The upper dome 152 may transmit infrared rays incident from a lower portion thereof. The infrared rays, reflected from the electromagnetic wave shield housing 130, may pass through the upper dome 152 to be incident on the substrate 174.

The lower dome 158 may be quartz or sapphire as a transparent dielectric material. The lower dome 158 may include a funnel-shaped lower dome body 158b, a washer-shaped coupling portion 158a coupled to the step formed on the lower surface of the chamber 160, and a cylindrical pipe 158c connected to a center of the lower dome body 158b. The lower dome 158 may be inserted into and coupled to the step spot formed on the lower surface of the chamber 160. A coupling portion 158a of the lower dome 158 coupled to the chamber 160 may have a washer shape to achieve vacuum sealing. The drive shaft of the first lifter 184 and the driving shaft of the second lifter 182 may be disposed to be inserted into the cylindrical pipe 158c. A purge gas supplied through the lower dome 158 may be supplied through a flow path. The flow path may be the cylindrical pipe 158c. The purge gas may be an inert gas such as argon.

The upper liner 154 may be a transparent dielectric material. The upper liner 154 may be quartz, alumina, sapphire, or aluminum nitride. The upper liner 154 may be formed of a material suppressing deposition of an abnormal thin film. When the upper liner 154 is contaminated, the contaminated upper liner 154 may be disassembled and cleaned. The upper liner 154 may have an overall ring shape, and an upper surface thereof may be a curved surface having the shape of the upper dome. The upper liner 154 may include a first opening 154a, formed on one side of the upper liner to exhaust a gas, and a second opening 154b formed on a side surface of the upper liner 154 to provide a passage of a substrate on the other side, opposing the first opening 154a of the upper liner 154. The first opening 154a may be aligned with the exhaust portion, and the second opening 154b may be aligned with the substrate entrance. An internal side surface of the upper liner 154 may vertically extend and may be connected to a tapered portion 154c tapered from a lower surface of the first opening 154a. A tapered internal surface may have the same inclination as an internal side surface of the lower liner 156. An angle of inclination θ of the inclined surface may be about 70 degrees. Accordingly, the purge gas may be stably supplied to an upper region of the chamber 160.

The upper liner 154 may include one or more process gas supply portions 159a and 159b supplying a process gas through a side surface of the upper liner 154. The process gas supply portions 159a and 159b may protrude from the side surface of the upper liner 154. For example, the process gas supply portion may include a first process gas supply portion 159a, supplying a first process gas such as SiH₄, and a second process gas supply portion 159b supplying a second process gas.

The first process gas supply portion 159a may protrude more from the side surface of the upper liner 154 such that the first process gas, such as SiH₄, is more exposed to plasma. On the other hand, the second process gas supply portion 159b may protrude less from the side surface of the upper liner such that the second process gas, such as a hydrogen gas (H₂), is less exposed to the plasma. Since the purge gas is introduced from the lower dome to the upper region of the chamber 160, the purge gas may be uniformly supplied on a circumference to have a spatially uniform pressure distribution.

The lower liner 156 may be coupled to the upper liner 154. The lower liner 156 may be disposed on an internal side of the chamber 160 to surround an internal circumferential surface of an upper edge of the lower dome 158, and may have a ring shape formed of an opaque dielectric material. The upper liner 154 may be disposed on the lower liner 156 to be aligned therewith and coupled thereto. The lower liner 156 may have an inclined lower external side surface 156b for being coupled to the lower dome 158 and an inclined lower internal side surface 156a for maintaining a continuous slope with the upper liner 154. The lower liner 156 may be formed of opaque quartz. For example, the lower line 156 may have an internal circumferential surface viewing a space of the lower dome 158, and the internal circumferential surface of the lower liner 156 may have an inclination at which a thickness is increased from a lower region to an upper region of the chamber 160 in a vertical direction. The angle of inclination θ of the internal circumferential surface may be about 70 degrees. The inclined internal circumferential surface may expose a lamp heater, disposed on an uppermost portion, to provide more uniform heating, and may scatter incident infrared rays to suppress the heating of the chamber 160.

A thermally insulating portion 162 may be disposed between the lower surface of the chamber 160 and a reflector 161 and may have a ring shape. The thermally insulating portion 162 may reduce heat transfer of the chamber 160 from the heated reflector 161. The thermally insulating portion 162 may be formed of a ceramic material. An upper surface of the thermally insulating portion 162 may include a step. The step of the thermally insulating portion 162 and the step of the lower surface of the chamber 160 may accommodate the washer-shaped coupling portion 158a of the lower dome and may vacuum-seal the coupling portion 158a.

The concentric lamp heaters 166 may include a plurality of ring-shaped concentric lamp heaters and may be connected to a power supply 164. The ring-shaped concentric lamp heaters may be disposed at regular intervals along the inclined surface of the lower dome 158, and the concentric lamp heaters 166 may be divided into three groups to be independently supplied with power. The ring-shaped concentric lamp heaters may be inserted into and aligned with a ring-shaped groove formed in an inclined surface of the reflector 161. For example, the concentric lamp heaters 166 may be halogen lamp heaters and eight concentric lamp heater 166 may be provided. Three lower lamp heaters may constitute a first group, two middle lamp heaters may constitute a second group, and three upper lamp heaters may constitute a third group. The first group may be connected to a first power supply 164a, the second group may be connected to a second power supply 164b, and the third group may be connected to a third power supply 164c. The first to third power supplies 164a to 164c may be independently controlled to uniformly heat the substrate.

The reflector 161 may support a lower surface of the thermally insulating portion 162 and may mount the lamp heater. An inclined surface, on which the lamp heater 166 is mounted, may have a conic shape to maintain a constant distance from the inclined surface of the lower dome 158. The reflector 161 may be formed of a conductor and may be cooled by cooling water.

A clamp 150 may be disposed to be in contact with the upper surface of the chamber 160 and to surround an edge of the upper dome 152. The clamp 150 may be a portion of the chamber 160 to serve as a lid of the chamber 160. The clamp 150 may be formed of a conductor and may be cooled by cooling water. A lower surface of the clamp 150 may have a step to be coupled to the washer-shaped coupling portion of the upper dome 152, and may include a curved surface portion 150a to surround a portion of a curved portion of the upper dome 152. The curved surface portion 150a of the clamp 150 may be plated with gold to reflect infrared rays. An internal diameter of the clamp 150 may be substantially the same as an internal diameter D of the upper liner 154. Also, the internal diameter of the clamp 150 may be the same as a diameter of the electromagnetic wave shield housing 130.

The antenna 110 may include two one-turn unit antennas 110a and 110b. The antennas 110 may be disposed to overlap each other on upper and lower surfaces, the one-turn unit antenna may have a shape of a strip line having a width greater than a thickness, and a width direction of the one-turn antenna may stand upright. The two one-turn unit antennas 110a and 110b may be connected to a radio-frequency (RF) power supply 140 in parallel. The RF power supply 140 may supply RF power to the antenna 110 through an impedance matching box 142 and the power supply line 143. The antenna 110 may include two one-turn unit antennas, the two one-turn unit antennas may be disposed to overlap with each other on the upper and lower surfaces, the two one-turn unit antennas may be connected to the RF power supply 140 in parallel, and a width direction of the one-turn unit antenna may stand upright.

An antenna, through which RF current flows, should secure a sufficient cross-sectional area for high current, and should form a closed loop to form sufficient magnetic flux. In addition, a plurality of turns may be required to ensure sufficient magnetic flux or high inductance. Accordingly, a stack structure may be required. However, an antenna having a width standing upright may not be generally used because the antenna occupies a large space and is disadvantageous in securing sufficient magnetic flux.

In the present disclosure, the antenna 110 may use a strip line standing upright to significantly reduce an increase in resistance caused by heating by absorbing infrared rays, incident from an upper or lower portion of the antenna. The antenna 110 may provide high transmissivity with respect to infrared rays.

Also, the antenna may be coated with gold (Au) or silver (Ag) to increase infrared reflection. In addition, an antenna having a two-layer structure may be used to secure sufficient magnetic flux. A one-turn unit antenna may reduce power loss, caused by capacitive coupling, because a position supplied with RF power is disposed on an upper surface of the one-turn unit antenna. An aspect ratio (a ratio W/t of a width W to a thickness t) of the strip line may be 10 or more. The strip line may have a thickness of several millimeters and a width of several centimeters. The standing-upright structure of the strip line does not interfere with a flow, resulting from introduction of air, and thus provide smooth air cooling. In addition, infrared rays reflected from the electromagnetic wave shield housing may significantly reduce a shadow formed by the antenna.

The lower surface of the antenna 110 may substantially be the same plane as the upper surface of the clamp 150 and may be higher than an uppermost position of the upper dome 152. Accordingly, the antenna 110 may not be in direct contact with the upper dome 152, and thus may not directly heat the upper dome 152 by heat transfer. The two one-turn unit antennas 110a and 110b may be disposed to rotate 180 degrees and overlap each other. Each of the one-turn unit antennas 110a and 110b may be disposed on the lower surface in a predetermined section and may be disposed on the upper surface in the remaining sections.

The one-turn unit antennas 110a and 110b may include radial portions 112a and 112b extending from the upper surface in a radial direction from a center of the one-turn unit antenna; first curved line portions 113a and 113b rotating 90 degrees clockwise along a circumference having a first radius R1 from a radius portion to extend from the upper surface; first vertical extending portions 114a and 114b changing an arrangement plane from the upper surface to the lower surface in the first curved line portion; second curved line portions 115a and 115b rotating 180 degrees clockwise along the circumference having the first radius R1 from the first vertical extending portion; second vertical extending portions 116a and 116b continuously connected to the second curved line portion, changing a radius from the first radius R1 to a second radius R2, smaller than the first radius R1, changing the placement surface from the lower surface to the upper surface, and changing a radius from the second radius R2 to the first radius R1; and third curved line portions 117a and 117b rotating 90 degrees clockwise from the second vertical extending portion along the circumference having the first radius R1 to extend from the upper surface. The third curved line portions 117a and 117b may be connected to a ground portion extending in the radial direction.

The electromagnetic wave shield housing 130 may be disposed to surround the antenna 110, and an internal surface of the electromagnetic wave shield housing 130 may be coated with gold (Au). The electromagnetic wave shield housing 130 may shield electromagnetic waves emitted from the antenna, and may reflect infrared rays emitted from the lamp heater. The electromagnetic wave shield housing 130 may be heated by a heater. A temperature of the electromagnetic wave shield housing may be 200 degrees Celsius to 600 degrees Celsius. The electromagnetic wave shield housing 130 may shield electromagnetic waves emitted by the antenna. The electromagnetic wave shield housing 130 may be formed of a material and may be heated by a heater embedded therein. The electromagnetic wave shield housing 130 may be grounded by an additional wire.

The thermally insulating spacer 339 may be thermally insulated from the electromagnetic wave shield housing 130 and the upper surface of the chamber 160 or the clamp 150. The thermally insulating spacer 339 may have a shape of a ring formed of a ceramic material. The thermally insulating spacer 339 may be covered with a wire mesh gasket. The wire mesh gasket may significantly reduce heat transfer while electrically connecting the electromagnetic wave shield housing 130 and the clamp 150 to each other.

A cooling housing 132 may be disposed to be spaced apart from each other to surround the electromagnetic wave shield housing 130. The cooling housing 132 may have a flow path therein and may be cooled by a refrigerant. The cooling housing 132 may be formed of a conductor and may be mounted on the clamp 150. The cooling housing 132 may block radiant heat, generated by the electromagnetic wave shield housing 130, to prevent damage to external components.

The cooling housing 132 may be disposed on the clamp 150 and may be disposed to surround the electromagnetic wave shield housing 130. The cooling housing 132 may be disposed to surround the electromagnetic wave shield housing 130. The cooling housing 132 may include a flow path 132a through which air is injected into and exhausted from the electromagnetic wave shield housing 130. The air, injected into the electromagnetic wave shield housing 130, may cool the antenna and the upper dome.

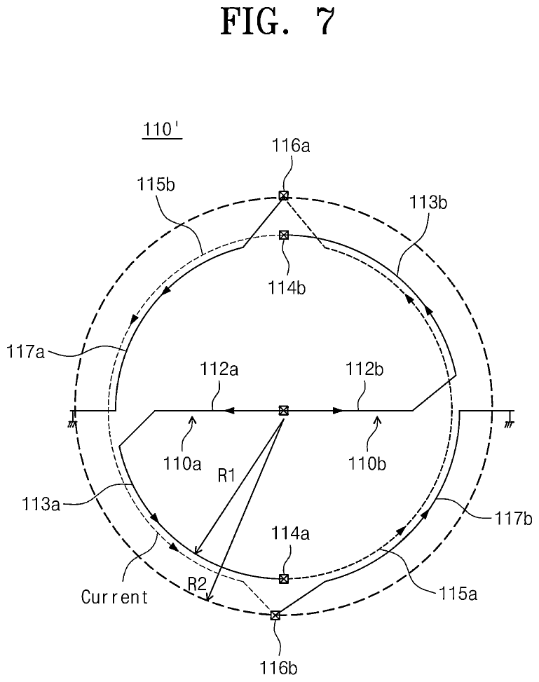

FIG. 7 is a plan view illustrating an antenna according to another embodiment of the present disclosure.

Referring to FIG. 7, an antenna 100′ may include two one-turn unit antennas 110a and 110b. The two one-turn unit antennas 110a and 110b may include radial portions 112a and 112b extending from an upper surface in a radial direction from a center of the one-turn unit antenna; first curved line portions 113a and 113b rotating 90 degrees clockwise along a circumference having a first radius R1 from the radius portion to extend from the upper surface; first vertical extending portions 114a and 114b changing an arrangement plane from the upper surface to a lower surface in the first curved line portion; second curved line portions 115a and 115b rotating 180 degrees clockwise along the circumference having the first radius R1 from the first vertical extending portion; second vertical extending portions 116a and 116b continuously connected to the second curved line portion, changing a radius from the first radius R1 to a second radius R2, larger than the first radius R1, changing the arrangement plane from the lower surface to the upper surface, and changing a radius from the second radius R2 to the first radius R1; and third curved line portions 117a and 117b rotating 90 degrees clockwise from the second vertical extending portion along a circumference having the first radius R1 to extend from the upper surface. The third curved line portions 117a and 117b may be connected to a ground portion extending in the radial direction.

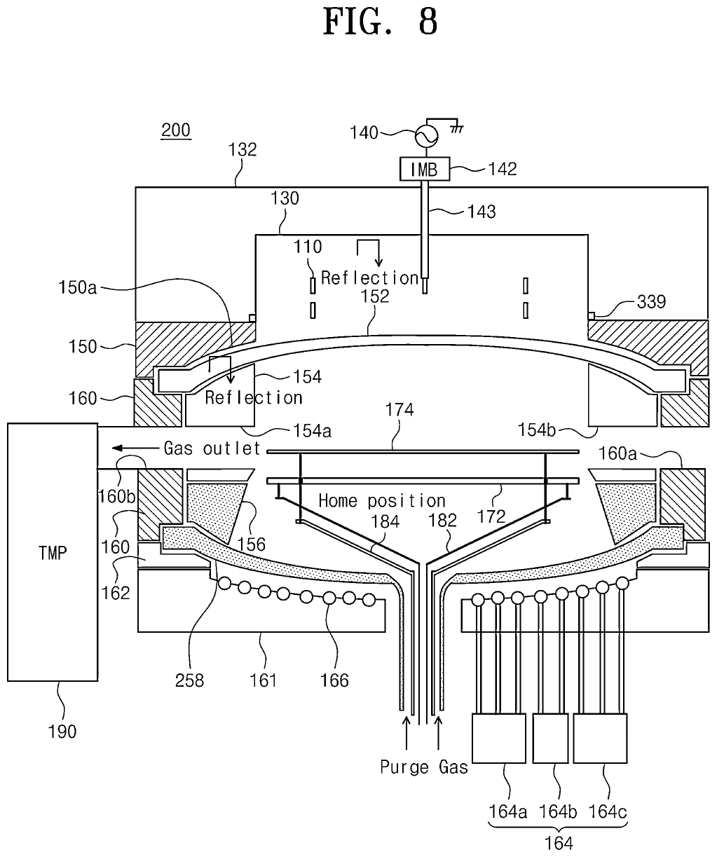

FIG. 8 is a conceptual diagram illustrating a plasma enhanced chemical vapor deposition apparatus according to another embodiment of the present disclosure.

Referring to FIG. 8, a plasma enhanced chemical vapor deposition apparatus 200 according to an embodiment may include a chamber 160 having a sidewall; a susceptor 172 mounting a substrate inside the chamber 160; an upper dome 152 surrounding an upper surface of the chamber 160 and formed of a transparent dielectric material; an antenna 110 disposed above the upper dome 152 to generate inductively-coupled plasma; and an electromagnetic wave shield housing 130 disposed to cover the antenna 110. The electromagnetic wave shield housing 130 may be heated by a heater.

The antenna 110 may include two one-turn unit antennas, and the two one-turn unit antennas may overlap each other on the upper and lower surfaces, and the two one-turn unit antennas may be connected to a radio-frequency (RF) power supply 140 in parallel, and a width direction of the one-turn unit antenna may stand upright.

A lower dome 258 may surround a lower surface of the chamber 160, may be formed of a transparent dielectric material, and may have the same curvature as the upper dome 152. A lamp heater may be disposed on a lower surface of the lower dome 258. A reflector may be disposed on a lower surface of the lamp heater.

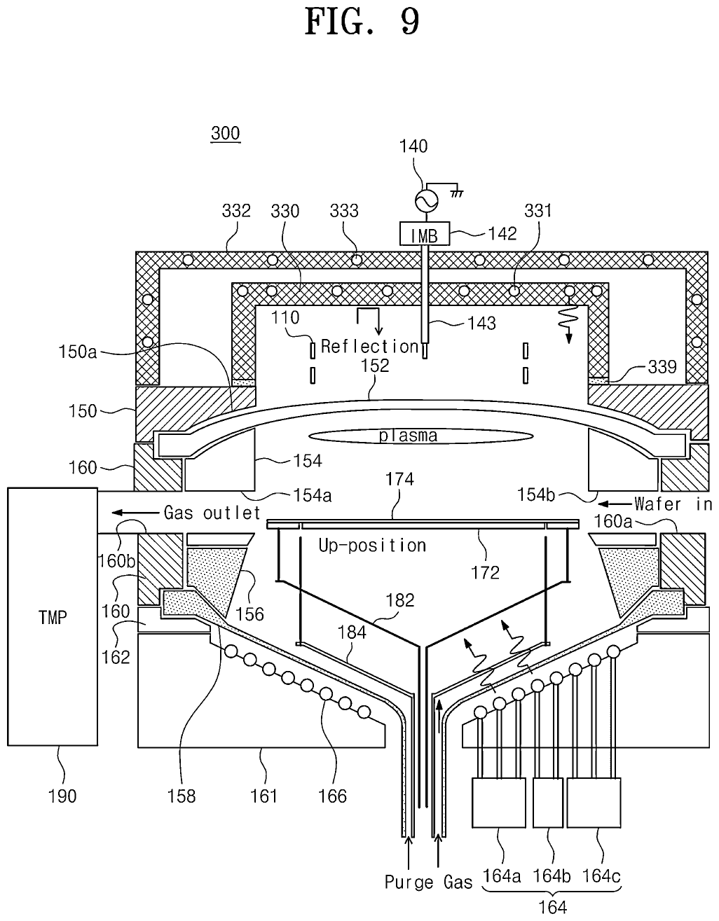

FIG. 9 is a conceptual diagram illustrating a plasma enhanced chemical vapor deposition apparatus according to another embodiment of the present disclosure.

Referring to FIG. 9, a plasma enhanced chemical vapor deposition apparatus 300 according to an embodiment may include a chamber 160 having a sidewall; a susceptor 172 mounting a substrate inside the chamber 160; an upper dome 152 surrounding an upper surface of the chamber 160 and formed of a transparent dielectric material; an antenna 110 disposed above the upper dome 152 to generate inductively-coupled plasma; and an electromagnetic wave shield housing 330 disposed to surround the antenna 110. The electromagnetic wave shield housing 330 may be heated by a heater.

The antenna 110 may include two one-turn unit antennas, the two one-turn unit antennas may be disposed to overlap each other on upper and lower surfaces, the two one-turn unit antennas may be connected to a radio-frequency (RF) power supply 140 in parallel, and a width direction of the one-turn unit antenna may stand upright.

The electromagnetic wave shield housing 330 may be disposed to surround the antenna 110, and an internal surface of the electromagnetic wave shield housing 330 may be coated with gold (Au). The electromagnetic wave shield housing 330 may be formed of a conductive material, having high reflectivity in an infrared band, such as metal. For example, the electromagnetic wave shield housing 330 may have a shape of a cylinder with a lid and may be formed of aluminum.

The electromagnetic wave shield housing 330 may be disposed on a clamp 150, may shield electromagnetic waves emitted from the antenna 110, may reflect infrared rays emitted from a lamp heater 166, and may be non-uniformly heated by absorbing infrared rays. An additional heater 331 may heat the electromagnetic wave shield housing 330 to spatially uniformly heat the electromagnetic wave shield housing 330. The heater 331 may be a resistive heater embedded in the electromagnetic wave shield housing 330. The resistive heater may be embedded in the lid of the electromagnetic wave shield housing 130 to have a spiral shape. Intervals between heaters may be decreased in a radial direction to achieve a spatially uniform temperature distribution. The uniformly heated electromagnetic wave shield housing 330 may additionally heat a substrate 174 through blackbody radiation. The heated electromagnetic wave shield housing 330 may not provide a temperature difference depending on an environment, and thus may improve process reliability.

A temperature of the electromagnetic wave shield housing 330 may be higher than a temperature at which the electromagnetic wave shield housing 330 is heated by the lamp heater 166. For example, the temperature of the electromagnetic wave shield housing 330 may range from 200 degrees Celsius to 600 degrees Celsius.

The antenna 110 may be additionally heated by the heated electromagnetic wave shield housing 330. However, the antenna 110 may absorb less radiant heat without interfering with a flow, caused by introduction of air, in the form of a strip standing upright and may be cooled by a smooth flow of the air.

The cooling housing 332 may be disposed on the clamp 150, and may be disposed to surround the electromagnetic wave shield housing 330. A space may be provided between the cooling housing 332 and the electromagnetic wave shield housing 330 to reduce heat loss caused by heat transfer. The space may have atmospheric pressure, and air filling the space may not be circulated.

The cooling housing 332 may include a flow path 333 through which a refrigerant flows, and the chamber housing may be cooled to room temperature. A cooling housing 332 may have a shape of a cylinder with a lid and may be formed of a conductive material.

An air flow path may pass through the cooling housing 332 and the electromagnetic wave shield housing 330 to inject air into a space formed by the electromagnetic wave shield housing 330. The air, injected into the electromagnetic wave shield housing 330, may cool the antenna 110 to provide a stable operation.

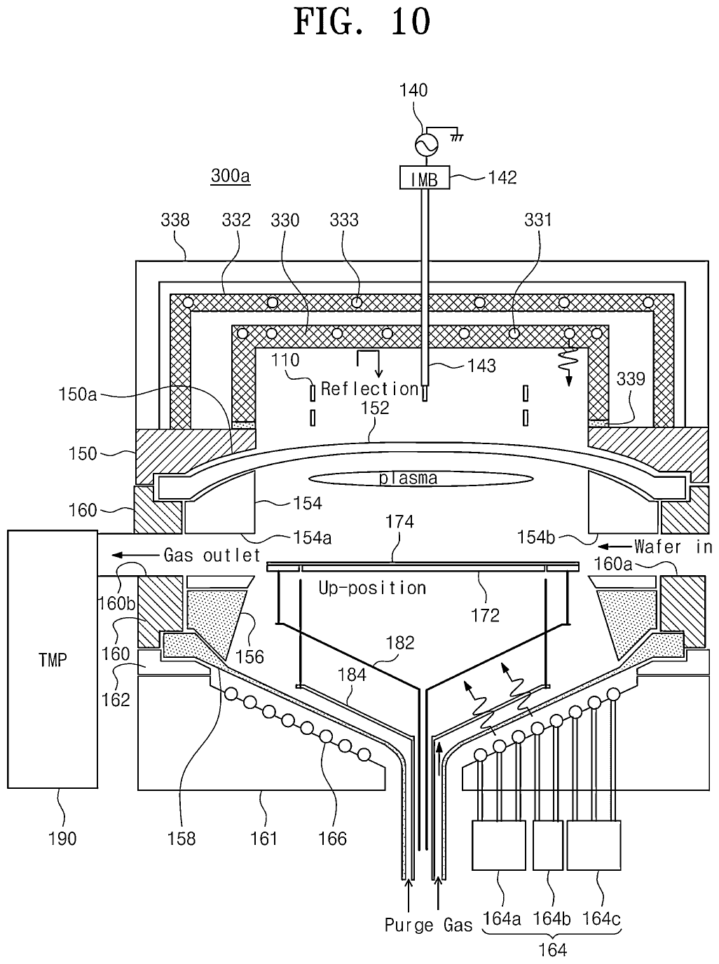

FIG. 10 is a conceptual diagram illustrating a plasma enhanced chemical vapor deposition apparatus according to another embodiment of the present disclosure.

Referring to FIG. 10, a plasma enhanced chemical vapor deposition apparatus 300a according to an embodiment may include a chamber 160 having a sidewall; a susceptor 172 mounting a substrate inside the chamber 160; an upper dome 152 surrounding an upper surface of the chamber 160 and formed of a transparent dielectric material; an antenna 110 disposed above the upper dome 152 to generate inductively-coupled plasma; and an electromagnetic wave shield housing 330 disposed to surround the antenna 110. The electromagnetic wave shield housing 330 may be heated by a heater.

A chamber housing 338 may be disposed to surround a cooling housing 332. An external device such as an impedance matching box 142 may be installed in the chamber housing 338. The chamber housing 338 may be grounded and may be formed of a conductor.

As described above, a substrate processing apparatus according to an example embodiment may perform selective epitaxial deposition by stably generate plasma even in a high-temperature process using a lamp heater.

Although the present disclosure and its advantages have been described in detail, it should be understood that various changes, substitutions and alterations can be made herein without departing from the spirit and scope of the disclosure as defined by the following claims.

What is claimed is:

1. A substrate processing apparatus comprising:
a chamber having a sidewall;
a susceptor configured to mount a substrate inside the chamber;
an upper dome surrounding an upper surface of the chamber and formed of a transparent dielectric material;
an antenna disposed above the upper dome to generate inductively-coupled plasma; and
an electromagnetic wave shield housing disposed to surround the antenna,
wherein
the electromagnetic wave shield housing is heated by a heater.

2. The substrate processing apparatus as set forth in claim 1, further comprising:
a thermally insulating spacer thermally insulated from the electromagnetic wave shield housing and an upper surface of the chamber.

3. The substrate processing apparatus as set forth in claim 2, wherein
the thermally insulating spacer has a shape of a ring formed of a ceramic material.

4. The substrate processing apparatus as set forth in claim 1, further comprising:
a cooling housing disposed to be spaced apart from the electromagnetic wave shield housing to surround the electromagnetic wave shield housing,
wherein
the cooling housing is cooled by a refrigerant.

5. The substrate processing apparatus as set forth in claim 1, wherein
a temperature of the electromagnetic wave shield housing ranges from 200 degrees Celsius to 600 degrees Celsius.

6. The substrate processing apparatus as set forth in claim 1, further comprising:
a funnel-shaped lower dome covering a lower surface of the chamber and formed of a transparent dielectric material;
a concentric lamp heater disposed on a lower surface of the lower dome;
a ring-shaped upper liner disposed on an internal side of the chamber, surrounding a lower side edge of the upper dome, and formed of a dielectric material;
a ring-shaped lower line disposed on the internal side of the chamber, surrounding an internal circumferential surface of an upper edge of the lower dome, and formed of a dielectric material; and
a reflector disposed on a lower surface of the concentric lamp heater.

7. The substrate processing apparatus as set forth in claim 1, wherein
the antenna comprises two one-turn unit antennas,
the two one-turn unit antennas are disposed to overlap each other on an upper surface and a lower surface,
the two one-turn unit antennas are connected to a radio-frequency (RF) power supply in parallel, and
a width direction of the one-turn unit antenna stands upright.

8. The substrate processing apparatus as set forth in claim 7, wherein
the one-turn unit antenna has a shape of a strip line having a width greater than a thickness of the strip line.
a width direction of the one-turn unit antenna stands upright, and
a ratio (W/t) of the width (W) to the thickness (t) is 10 or more.
